(19) United States
(12) Patent Application Publication
(10) Pub. No.: US 2015/0223325 A1
(43) Pub. Date: Aug. 6, 2015

(54) WIRING BOARD, METHOD OF MANUFACTURING WIRING BOARD, ELECTRONIC DEVICE, ELECTRONIC APPARATUS, AND MOVING OBJECT

(71) Applicant: Seiko Epson Corporation, Tokyo (JP)

(72) Inventors: Tetsuro MIYAO, Suwa (JP); Hideki ISHIGAMI, Hachinohe (JP); Yukihiko SHIOHARA, Hachinohe (JP); Tetsuya OTSUKI, Fujimi (JP); Hidefumi NAKAMURA, Hachinohe (JP)

(21) Appl. No.: 14/612,638

(22) Filed: Feb. 3, 2015

(30) Foreign Application Priority Data
Feb. 4, 2014 (JP) 2014-019787

(51) Int. Cl. H05K 1/02; H05K 3/40; H05K 1/11; H05K 1/18; H05K 1/03; H05K 1/09

(52) U.S. Cl. CPC H05K 1/0271; H05K 1/0306; H05K 1/09; H05K 1/115; H05K 1/184; H05K 3/4061

(57) ABSTRACT

A base substrate includes a ceramic sintered substrate having through holes, first and second metal wirings which are integrally disposed so as to be connected to the surface of the ceramic sintered substrate and the inside of the through holes, and first and second active metal layers which are disposed between the ceramic sintered substrate and the first and second metal wirings.

### BACKGROUND

1. Technical Field

The present invention relates to a wiring board, a method of manufacturing the same, an electronic device, an electronic apparatus, and a moving object.

2. Related Art

For example, a manufacturing method disclosed in JP-A-2013-153051 is known as a method of manufacturing a wiring board (circuit board). That is, first, a ceramic sintered substrate having a through hole is prepared. Next, the through hole is filled with a first metal paste containing titanium hydride powder and copper powder by using a printing method, and thermal drying is performed thereon at a temperature of approximately 100° C., thereby forming a first metal paste layer. Next, a second metal paste containing titanium hydride powder, copper powder, and silver powder is printed on the surface of the ceramic sintered substrate, and thermal drying is performed thereon at a temperature of approximately 100° C., thereby forming a second metal paste layer. Next, a third metal paste containing silver-copper alloy powder is printed on the second metal paste layer, and thermal drying is performed thereon at a temperature of approximately 100° C., thereby forming a third metal paste layer. Next, the first to third metal paste layers are baked at a temperature of approximately 900° C., a conductive via is formed in the through hole, and a surface conductive layer is formed on the surface of the substrate. Thereby, the wiring board is obtained. According to the manufacturing method, an active layer is formed between the ceramic sintered substrate, the conductive via and the surface conductive layer, and thus an effect of improving adhesion between the ceramic sintered substrate, the conductive via and the surface conductive layer is obtained.

However, in this manufacturing method, printing and thermal drying have to be repeated multiple times. For this reason, for example, the following problem occurs. Firstly, a manufacturing cost rises due to the printing and thermal drying being repeated multiple times. Secondly, a thermal history increases due to the printing and thermal drying being repeated multiple times. Thereby, the residual stress of the ceramic sintered substrate becomes large, and there is a concern that distortion (deformation, bending) and a crack may occur. Thirdly, since the printing is repeated multiple times, there is a tendency for a wiring to be deformed, and the thickness of the wiring may become unstable. For this reason, there is an increasing concern that disconnection and a short circuit may occur.

### SUMMARY

An advantage of some aspects of the invention is to provide a wiring board that can be manufactured through a small number of processes and has excellent adhesion between a metal wiring and a substrate, a method of manufacturing the wiring board, and an electronic device, an electronic apparatus, and a moving object which include the wiring board and have excellent reliability.

The invention can be implemented as the following application examples.

### APPLICATION EXAMPLE 1

This application example is directed to a wiring board including a substrate which includes a concave portion having an opening in a surface thereof; a metal wiring which is disposed so as to be connected to the surface of the substrate and the inside of the concave portion; and an active metal layer which is disposed between the metal wiring and the substrate and contains an active metal active for a component contained in the substrate.

With this configuration, the wiring board having excellent adhesion between the metal wiring and the substrate is obtained.

### APPLICATION EXAMPLE 2

In the wiring board according to the application example, it is preferable that the substrate is a ceramic substrate and that the active metal layer is formed by reaction occurring between the active metal and a ceramic component contained in the ceramic substrate.

With this configuration, the wiring board having excellent adhesion between the metal wiring and the substrate is obtained.

### APPLICATION EXAMPLE 3

In the wiring board according to the application example, it is preferable that the active metal layer contains a metal belonging to Group IV of a periodic table as the active metal.

With this configuration, the active metal layer with good quality is obtained.

### APPLICATION EXAMPLE 4

In the wiring board according to the application example, it is preferable that the active metal layer contain titanium as the active metal.

With this configuration, it is possible to form the active metal layer at a relatively low temperature, and, it is possible to reduce thermal damage to the substrate, for example.

### APPLICATION EXAMPLE 5

In the wiring board according to the application example, it is preferable that the metal wiring contains a metal belonging to Group VI of a periodic table, silver, and copper.

With this configuration, the conductivity and wiring shape retaining properties of the metal wiring are improved.

### APPLICATION EXAMPLE 6

In the wiring board according to the application example, it is preferable that the metal wiring contains tungsten as the metal belonging to Group VI.

With this configuration, since the metal belonging to Group VI is not more likely to be melted during the manufacture of the metal wiring, the conductivity and wiring shape retaining properties of the metal wiring are further improved.

### APPLICATION EXAMPLE 7

In the wiring board according to the application example, it is preferable that the concave portion is a through hole passing through one principal surface and the other principal surface of the substrate.

With this configuration, it is possible to use the metal wiring disposed in the concave portion as a via.

### APPLICATION EXAMPLE 8

This application example is directed to a method of manufacturing a wiring board, the method including preparing a substrate that includes a concave portion having an opening in a surface thereof, and a mixture of a first particle constituted by an alloy containing an active metal, which belongs to Group IV of a periodic table and is active for a component contained in the substrate, silver, and copper and a second particle constituted by a metal belonging to Group VI of the periodic table or an alloy containing the metal belonging to Group VI; disposing the mixture so as to be connected to the surface of the substrate and the inside of the concave portion; and forming a metal wiring by baking the mixture disposed on the substrate.

With this configuration, the active metal layer is formed between the metal wiring and the substrate, and thus it is possible to form the wiring board having excellent adhesion between the metal wiring and the substrate. In addition, it is possible to manufacture the wiring board through a small number of processes.

### APPLICATION EXAMPLE 9

In the method according to the application example, it is preferable that the substrate is a ceramic substrate and that the active metal is active for a ceramic component contained in the ceramic substrate.

With this configuration, the wiring board having excellent adhesion between the metal wiring and the substrate is obtained.

### APPLICATION EXAMPLE 10

In the method according to the application example, it is preferable that a baking temperature of the mixture is lower than a baking temperature of the ceramic substrate in the forming of the metal wiring.

With this configuration, it is possible to reduce thermal damage to the ceramic substrate.

### APPLICATION EXAMPLE 11

In the method according to the application example, it is preferable that the first particle contains titanium as the active metal.

With this configuration, since a satisfactory active metal layer is formed between the substrate and the metal wiring, the adhesion between the substrate and the metal wiring is further improved.

### APPLICATION EXAMPLE 12

In the method according to the application example, it is preferable that the second particle contains tungsten as the metal belonging to Group VI.

With this configuration, it is possible to effectively suppress the melting of the metal belonging to Group VI during the manufacture of the wiring board. Therefore, the wiring shape retaining properties and conductivity of the wiring board become satisfactory.

### APPLICATION EXAMPLE 13

In the method according to the application example, it is preferable that the second particle is an alloy containing the metal belonging to Group VI and nickel.

With this configuration, the adhesion between the active metal layer and the metal wiring is further improved.

### APPLICATION EXAMPLE 14

In the method according to the application example, it is preferable that a content of the first particle with respect to a total weight of the first particle and the second particle in the mixture is in a range between equal to or higher than 35% by weight and equal to or lower than 85% by weight.

With this configuration, it is possible to form a more satisfactory active metal layer.

### APPLICATION EXAMPLE 15

This application example is directed to an electronic device including the wiring board according to the application example described above and an electronic component which is mounted on the wiring board.

With this configuration, the electronic device with high reliability is obtained.

### APPLICATION EXAMPLE 16

This application example is directed to an electronic apparatus including the electronic device according to the application example described above.

With this configuration, the electronic apparatus with high reliability is obtained.

### APPLICATION EXAMPLE 17

This application example is directed to a moving object including the electronic device according to the application example described above.

With this configuration, the moving object with high reliability is obtained.

### BRIEF DESCRIPTION OF THE DRAWINGS

The invention will be described with reference to the accompanying drawings, wherein like numbers reference like elements.

FIG. 1 is a plan view of an electronic device according to a first embodiment of the invention.

FIG. 2 is a cross-sectional view taken along line A-A in FIG. 1.

FIGS. 3A and 3B are plan views of a vibrating element included in the electronic device shown in FIG. 1.

FIG. 4 is a partially enlarged cross-sectional view of a base substrate included in the electronic device shown in FIG. 1.

FIGS. 5A to 5C are diagrams illustrating a method of manufacturing the base substrate shown in FIG. 4.

FIG. 6 is a diagram illustrating the method of manufacturing the base substrate shown in FIG. 4.

FIG. 7 is a perspective view showing the configuration of a mobile (or notebook) personal computer to which an electronic apparatus according to the invention is applied.

FIG. 8 is a perspective view showing the configuration of a mobile phone (a PHS is also included) to which an electronic apparatus according to the invention is applied.

FIG. 9 is a perspective view showing the configuration of a digital still camera to which an electronic apparatus according to the invention is applied.

FIG. 10 is a perspective view showing a vehicle to which a moving object according to the invention is applied.

FIG. 11 is a table showing the evaluation of examples.

FIG. 12 is an SEM image showing a base substrate.

FIG. 13 is a graph showing the content of metals in a ceramic sintered substrate, an active metal layer, and a metal wiring shown in FIG. 12.

### DESCRIPTION OF EXEMPLARY EMBODIMENTS

Hereinafter, a wiring board, a method of manufacturing the wiring board, an electronic device, an electronic apparatus, and a moving object according to the invention will be described in detail on the basis of preferred embodiments shown in the accompanying drawings.

### 1. Electronic Device

First, an electronic device including a wiring board according to the invention will be described.

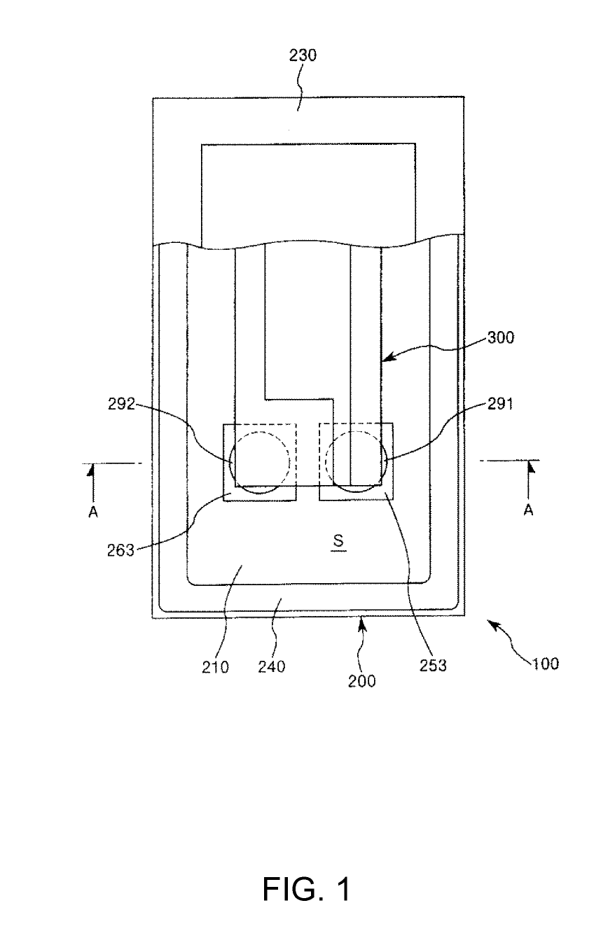

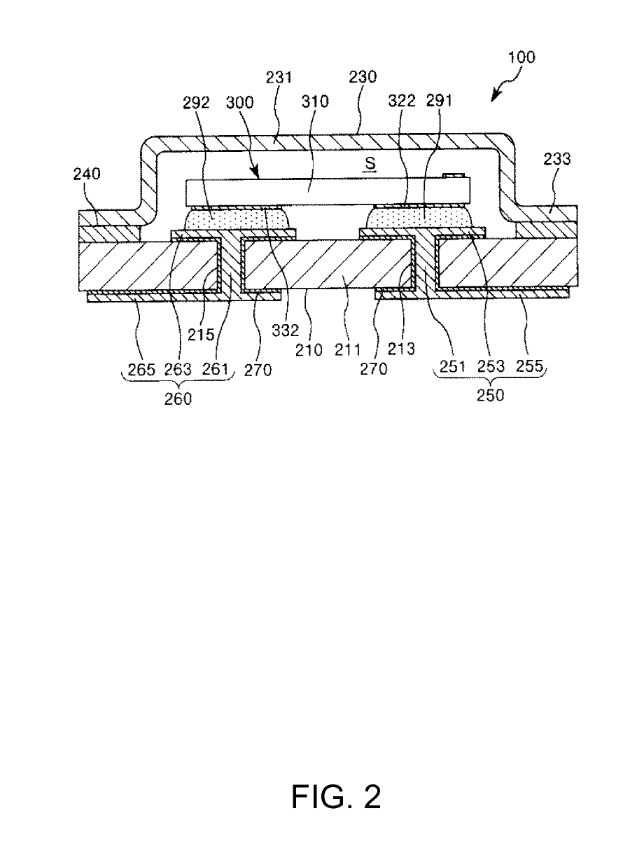

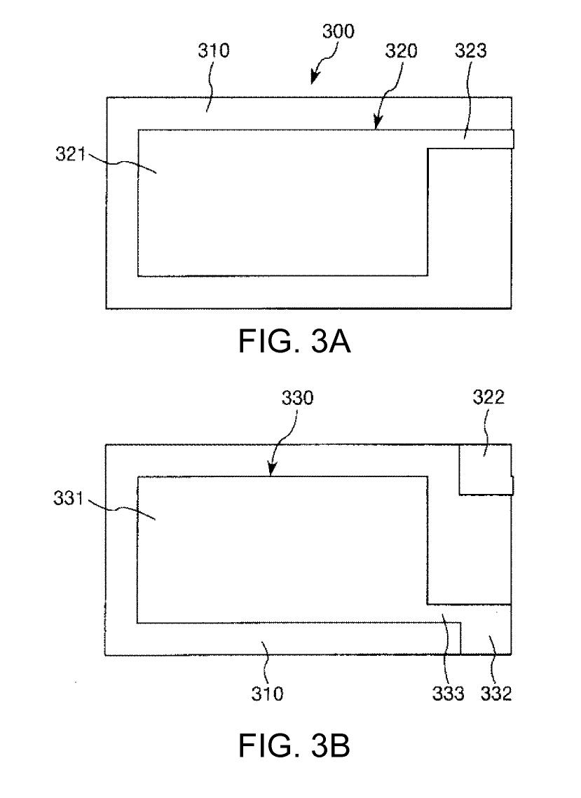

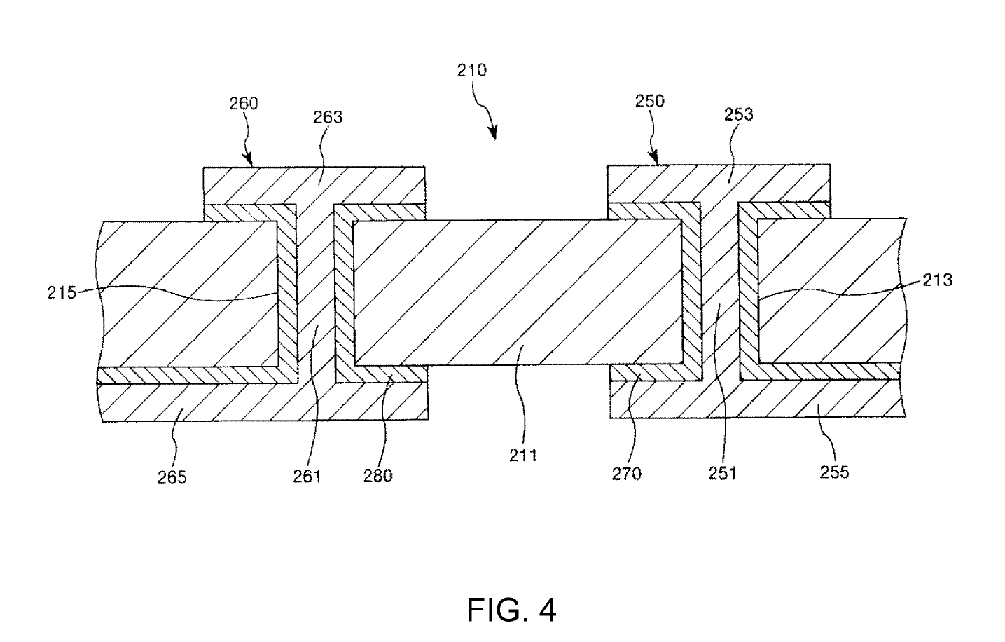

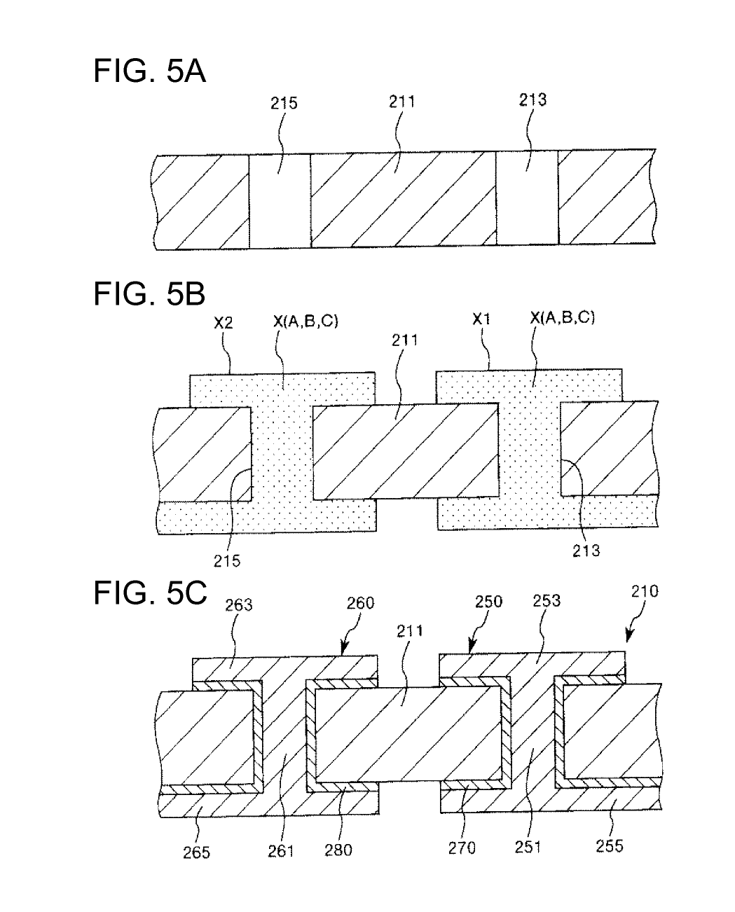

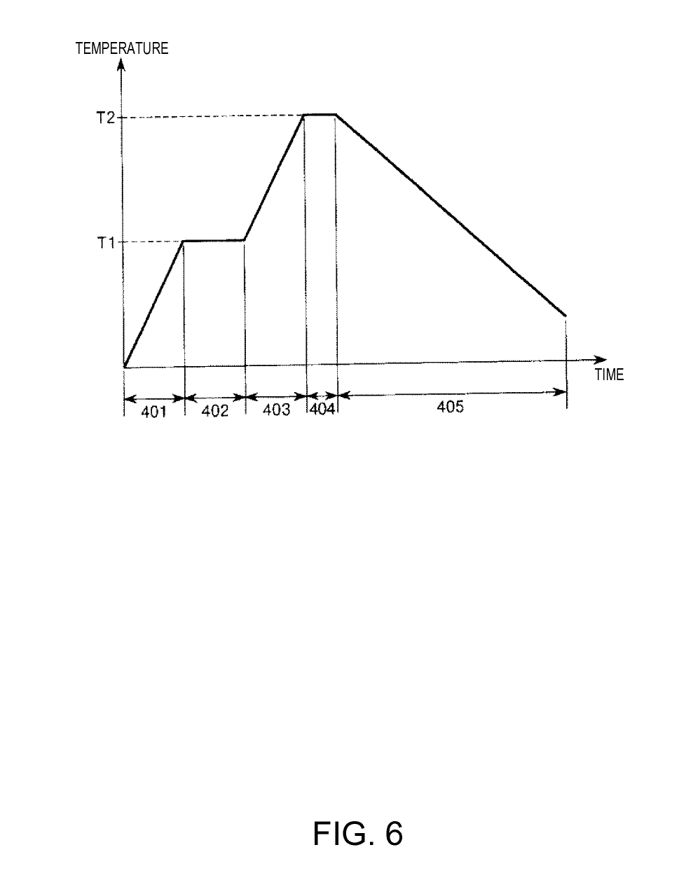

FIG. 1 is a plan view of an electronic device according to a first embodiment of the invention. FIG. 2 is a cross-sectional view taken along line A-A in FIG. 1. FIGS. 3A and 3B are plan views of a vibrating element included in the electronic device shown in FIG. 1. FIG. 4 is a partially enlarged cross-sectional view of a base substrate included in the electronic device shown in FIG. 1. FIGS. 5A to 5C and FIG. 6 are diagrams illustrating a method of manufacturing the base substrate shown in FIG. 4. Hereinafter, for convenience of description, the description will be given on the assumption that an upper side in FIG. 2 is “up” and a lower side is “down” (the same is true of other drawings).

As shown in FIGS. 1 and 2, an electronic device 100 includes a package 200 and a vibrating element 300 as an electronic component which is accommodated in the package 200. Meanwhile, the electronic component is not limited to the vibrating element 300, and various types of electronic components such as, for example, an IC chip may be used.

### Vibrating Element

FIG. 3A is a plan view when the vibrating element 300 is seen from above, and FIG. 3B is a perspective view (plan view) when the vibrating element 300 is seen from above. As shown in FIGS. 3A and 3B, the vibrating element 300 includes a piezoelectric substrate 310 having a rectangular plate shape when seen in a plan view and a pair of exciting electrodes 320 and 330 which are formed on the surface of the piezoelectric substrate 310.

The piezoelectric substrate 310 is a quartz crystal blank plate that mainly generates a thickness shear vibration. In this embodiment, a quartz crystal blank plate cut out at a cut angle called an AT-cut is used as the piezoelectric substrate 310. Meanwhile, the AT-cut refers to cutting-out performed to have a principal surface (principal surface including an X-axis and a Z′-axis) which is obtained by rotating a plane (Y-plane) including an X-axis and a Z-axis, which are crystal axes of a quartz crystal, counterclockwise around the X-axis from the Z-axis by approximately 35.15 degrees. The longitudinal direction of the piezoelectric substrate 310 coincides with the X-axis which is a crystal axis of a quartz crystal.

The exciting electrode 320 includes an electrode portion 321 formed on the top surface of the piezoelectric substrate 310, a bonding pad 322 formed on the bottom surface of the piezoelectric substrate 310, and a wiring 323 that electrically connects the electrode portion 321 and the bonding pad 322. On the other hand, the exciting electrode 330 includes an electrode portion 331 formed on the bottom surface of the piezoelectric substrate 310, a bonding pad 332 formed on the bottom surface of the piezoelectric substrate 310, and a wiring 333 that electrically connects the electrode portion 331 and the bonding pad 332.

For example, the exciting electrodes 320 and 330 can be formed by forming a ground layer of nickel (Ni) or chromium (Cr) on the piezoelectric substrate 310 by deposition or sputtering, forming an electrode layer of gold (Au) on the ground layer by deposition or sputtering, and then patterning the electrode layer into a desired shape by using a photolithography technique and an etching technique. The adhesiveness between the piezoelectric substrate 310 and the electrode layer is improved by forming the ground layer, and thus the vibrating element 300 with high reliability is obtained.

Meanwhile, the configurations of the exciting electrodes 320 and 330 are not limited to the above-mentioned configurations. For example, the ground layer may be omitted, and other conductive materials (various types of metal materials such as, for example, silver (Ag), copper (Cu), tungsten (W), and molybdenum (Mo)) may be used as the constituent materials thereof.

The vibrating element 300 is fixed to the package 200 through a pair of conductive adhesives 291 and 292.

### Package

As shown in FIGS. 1 and 2, the package 200 includes a plate-shaped base substrate (wiring board according to the invention) 210, a cap-shaped lid 230 which includes a concave portion opening to a lower side, and a metalized layer 240 which is interposed between the base substrate 210 and the lid 230 to bond the base substrate and the lid together. In the package 200, an opening of a concave portion of the lid 230 is blocked by the base substrate 210, and thus an airtight accommodation space S accommodating the vibrating element 300 mentioned above is formed.

The lid 230 includes a box-shaped main body 231 and a flange 233 which is formed at a lower end of the main body 231 (that is, in the vicinity of the opening of the main body 231). In addition, a metal brazing material, not shown in the drawing, is provided on the bottom surface of the flange 233 in the form of a film so as to surround the vicinity of the opening. The lid 230 is bonded to the base substrate 210 by welding the metal brazing material and the metalized layer 240 together. Meanwhile, the metal brazing material is not particularly limited. For example, gold solder, silver solder, and the like can be used as the metal brazing material, but silver solder is preferably used. In addition, a constituent material of the lid 230 is not particularly limited. However, a member having a linear expansion coefficient which approximates that of the constituent material of the base substrate 210 (ceramic sintered substrate 211 to be described later) may be used as the constituent material, and is preferably an alloy such as, for example, Kovar.

As shown in FIGS. 2 and 4, the base substrate 210 includes a plate-shaped ceramic sintered substrate (ceramic substrate) 211 that includes two through holes (concave portions) 213 and 215 passing through the top and bottom surfaces (one principal surface and the other principal surface) thereof, a first metal wiring 250 which is formed so as to be connected to the top and bottom surfaces of the ceramic sintered substrate 211 and the inside of each through hole 213, a second metal wiring 260 which is formed so as to be connected to the top and bottom surfaces of the ceramic sintered substrate 211 and the inside of each through hole 215, a first active metal layer 270 which is disposed between the first metal wiring 250 and the ceramic sintered substrate 211, and a second active metal layer 280 which is disposed between the second metal wiring 260 and the ceramic sintered substrate 211.

The ceramic sintered substrate 211 may have a single-layer structure or may have a stacked structure in which a plurality of layers (sheets) are stacked. However, in this embodiment, a ceramic sintered substrate having a single-layer structure is used. Thus, it is possible to achieve a reduction in the thickness of the ceramic sintered substrate 211 and to a reduction in a manufacturing cost.

A method of forming the through holes 213 and 215 in the ceramic sintered substrate 211 is not particularly limited. For example, the through holes may be formed by punching or the like before a sintering process or may be formed by laser processing, etching processing, and drilling processing, or the like after a sintering process. However, since the ceramic sintered substrate 211 contracts due to the sintering process, it is preferable that the through holes are formed after the sintering process if the accuracy of the arrangement and size of the through holes 213 and 215 is desired to be increased. The diameters of the through holes 213 and 215 are not particularly limited, but can be set to, for example, approximately equal to or greater than 20 μm and approximately equal to or less than 100 μm.

Ceramic which is the constituent material of the ceramic sintered substrate 211 is not particularly limited. However, it is possible to use, for example, oxide-based ceramics such as aluminum oxide-based ceramics, silicon oxide-based ceramics, calcium oxide-based ceramics, or magnesium oxide-based ceramics, nitride-based ceramics such as aluminum nitride-based ceramics, silicon nitride-based ceramics, or boron nitride-based ceramics, beryllium oxide, silicon carbide, mullite, borosilicate glass, and the like.

The ceramic sintered substrate 211 is obtained by molding a mixed material including ceramic powder, a sintering aid, an organic binder, and the like into a sheet shape to thereby obtain a green sheet and performing a sintering process on the green sheet. Meanwhile, a well-known sintering aid can be used as the sintering aid according to the types of ceramic powder used. In addition, for example, polyvinyl butyral, ethyl cellulose, acrylic resins, or the like can be used as the organic binder.

The first metal wiring 250 includes a via 251 which is disposed within the through hole 213, an internal terminal 253 which is disposed on the top surface of the ceramic sintered substrate 211 so as to overlap the via 251, and a mounting terminal 255 which is disposed on the bottom surface of the ceramic sintered substrate 211 so as to overlap the via 251. The via 251, the internal terminal 253, and the mounting terminal 255 are integrally formed. Similarly, the second metal wiring 260 includes a via 261 which is disposed within the through hole 215, an internal terminal 263 which is disposed on the top surface of the ceramic sintered substrate 211 so as to overlap the via 261, and a mounting terminal 265 which is disposed on the bottom surface of the ceramic sintered substrate 211 so as to overlap the via 261. The via 261, the internal terminal 263, and the mounting terminal 265 are integrally formed. Meanwhile, the configurations of the first and the second metal wirings 250 and 260 are not limited to those in this embodiment. For example, in this embodiment, both the internal terminal 253 and the mounting terminal 255 are disposed so as to overlap the via 251. Unlike this, both the internal terminal 253 and the mounting terminal 255 may be disposed at a location that does not overlap the via 251. In this case, the first metal wiring 250 further includes a top surface side wiring which is disposed on the top surface of the ceramic sintered substrate 211 and connects the via 251 and the internal terminal 253 and a bottom surface side wiring which is disposed on the bottom surface of the ceramic sintered substrate 211 and connects the via 251 and the mounting terminal 255. The same is true of the second metal wiring 260.

In addition, as shown in FIG. 2, the internal terminal 253 is electrically connected to the bonding pad 322 of the vibrating element 300 through the conductive adhesive 291, and the internal terminal 263 is electrically connected to the bonding pad 332 of the vibrating element 300 through the conductive adhesive 292.

It is preferable that the first and second metal wirings 250 and 260 include a metal (element) belonging to Group VI of the periodic table, silver, and copper. Examples of the metal belonging to Group VI of the periodic table include chromium (Cr), molybdenum (Mo), and tungsten (W), and at least one of the metals may be used. Meanwhile, for convenience of description, the metal belonging to Group VI of the periodic table will be simply referred to as a “metal of Group VI” below. Since the metals of Group VI have a melting point sufficiently higher than those of silver and copper included together, the metal of Group VI is not melted during a manufacturing process to be described later, and thus it is possible to satisfactorily maintain the shapes of the first and second metal wirings 250 and 260 (particularly, the shapes of the vias 251 and 261). For this reason, the metals of Group VI have excellent shape retaining properties and conductivity. Meanwhile, the melting point of silver is approximately 962° C., the melting point of copper is approximately 1085° C., the melting point of chromium is approximately 1907° C., the melting point of molybdenum is approximately 2617° C., and the melting point of tungsten is approximately 3410° C. Accordingly, it is possible to effectively exhibit the above-mentioned effects by using tungsten which has the highest melting point in the metals of Group VI.

The configurations of the ceramic sintered substrate 211 and the first and second metal wirings 250 and 260 have been described so far. In the base substrate 210, the first active metal layer 270 is disposed between the ceramic sintered substrate 211 and the first metal wiring 250, and the second active metal layer 280 is disposed between the ceramic sintered substrate 211 and the second metal wiring 260.

Specifically, the first active metal layer 270 is disposed between the via 251 and the inner circumferential surface of the through hole 213, between the internal terminal 253 and the top surface of the ceramic sintered substrate 211, and between the mounting terminal 255 and the bottom surface of the ceramic sintered substrate 211. The via 251 is bonded to the inner circumferential surface of the through hole 213, the internal terminal 253 is bonded to the top surface of the ceramic sintered substrate 211, and the mounting terminal 255 is bonded to the bottom surface of the ceramic sintered substrate 211 through the first active metal layer 270. Similarly, the second active metal layer 280 is specifically disposed between the via 261 and the inner circumferential surface of the through hole 215, between the internal terminal 263 and the top surface of the ceramic sintered substrate 211, and the mounting terminal 265 and the bottom surface of the ceramic sintered substrate 211. In addition, the via 261 is bonded to the inner circumferential surface of the through hole 215, the internal terminal 263 is bonded to the top surface of the ceramic sintered substrate 211, and the mounting terminal 265 is bonded to the bottom surface of the ceramic sintered substrate 211 through the second active metal layer 280.

Consequently, the first and second active metal layers 270 and 280 refer to layers formed at an interface with the ceramic sintered substrate 211 through a reaction occurring between active metals contained in the first and second active metal layers 270 and 280 and a ceramic component contained in the ceramic sintered substrate 211. The adhesion between the ceramic sintered substrate 211 and the first and second metal wirings 250 and 260 is increased by forming the first and second active metal layers 270 and 280. Therefore, even when silver (Ag) and copper (Cu) having a low adhesion with respect to ceramics are used as the materials of the first and second metal wirings 250 and 260 as described above, it is possible to secure the adhesion of the vias 251 and 261.

The first and second active metal layers 270 and 280 contain a metal (element) belonging to Group IV(A) of the periodic table as the active metal. Since a metal belonging to Group IV of the periodic table can be suitably used as the active metal, it is possible to more reliably form the first and second active metal layers 270 and 280. Meanwhile, examples of the metal belonging to Group IV(A) of the periodic table include titanium (Ti), zirconium (Zr), and hafnium (Hf). Any one of these metals may be used, but titanium (Ti) is preferably used among these metals. Among titanium (Ti), zirconium (Zr), and hafnium (Hf), titanium has the lowest melting point. Therefore, it is possible to prevent the above-mentioned metal of Group VI from being unintentionally melted during the manufacture of the layers and to lower a baking temperature at the time of forming the first and second active metal layers 270 and 280, and thus it is possible to reduce thermal damage to the ceramic sintered substrate 211.

Meanwhile, the thicknesses (average thicknesses) of the first and second active metal layers 270 and 280 are not particularly limited, but are preferably, for example, approximately equal to or greater than 1 μm and approximately equal to or less than 20 μm . Thus, it is possible to make the first and second active metal layers 270 and 280 have sufficient thicknesses while preventing the thicknesses of the first and second active metal layers 270 and 280 from being excessively increased. Therefore, it is possible to sufficiently increase the adhesion between the ceramic sintered substrate 211 and the first and second metal wirings 250 and 260 while suppressing an increase in the size of the base substrate 210.

### 2. Method of Manufacturing Base Substrate

Next, a method of manufacturing the base substrate (wiring board) 210 included in the electronic device 100 mentioned above will be described.

The method of manufacturing the base substrate 210 includes a first process of preparing the ceramic sintered substrate 211 having the through holes (concave portions) 213 and 215, a second process of disposing a metal paste (mixture) X, including a first particle A constituted by an alloy containing a metal of Group IV, silver, and copper and a second particle B constituted by an alloy containing a metal of Group VI, so as to be connected to the top and bottom surfaces of the ceramic sintered substrate 211 and the inside of the through holes 213 and 215, and a third process of forming the first and second metal wirings 250 and 260 and the first and second active metal layers 270 and 280 by baking the metal paste X disposed on the ceramic sintered substrate 211.

### First Process

For example, the ceramic sintered substrate 211 is obtained by molding a mixed material containing ceramic powder, a sintering aid, an organic binder, and the like into a sheet shape to thereby obtain a green sheet and performing a sintering process on the green sheet. The through holes 213 and 215 may be formed by punching or the like before performing the sintering process, or may be formed by laser processing, etching processing, drilling, or the like after performing the sintering process. However, the ceramic sintered substrate 211 contracts by the sintering process. For this reason, when the through holes 213 and 215 are formed before performing the sintering process, there is a concern that the accuracy of the arrangement and size of the through holes may be decreased. Therefore, it is preferable that the through holes are formed after performing the sintering process if the accuracy of the arrangement and size of the through holes 213 and 215 is desired to be increased. Meanwhile, the diameters of the through holes 213 and 215 are not particularly limited, but can be set to, for example, approximately equal to or greater than 20 μm and approximately equal to or less than 100 μm.

### Second Process

### Process of Preparing Metal Paste X

A first particle A constituted by a first alloy (M₄-Ag—Cu-based alloy) containing a metal of Group IV M₄, silver (Ag), and copper (Cu), a second particle B constituted by a second alloy (M₆-Ni-based alloy) containing a metal of Group VI M₆ and nickel (Ni), and a binder C are prepared, and the particles are mixed together to thereby obtain the metal paste X.

The metal of Group IV M₄ contained in the first alloy is an active metal which has a tendency to react with the ceramic component (that is, which is active for the ceramic component) which is contained in the ceramic sintered substrate 211. The active metal means a meal having a tendency to react with a certain material. Therefore, the first alloy contains the metal of Group IV M₄, thereby allowing the first and second active metal layers 270 and 280 to be formed at an interface with the ceramic sintered substrate 211 in the third process. Any one of titanium (Ti), zirconium (Zr), and hafnium (Hf) may be used as the metal of Group IV M₄, but titanium (Ti) is preferably used among these metals. Among these metals, titanium (Ti) has the lowest melting point, and thus it is possible to decrease a baking temperature in the third process. Therefore, it is possible to reduce thermal damage to the ceramic sintered substrate 211 in the third process.

Meanwhile, the content (concentration % by weight) of the metal of Group IV M₄ in the first alloy is not particularly limited. However, for example, the content is preferably approximately equal to or higher than 2% by weight and approximately equal to or lower than 20% by weight and is more preferably approximately equal to or higher than 7% by weight and approximately equal to or lower than 11% by weight. Thus, it is possible to sufficiently secure the content of the metal of Group IV M₄ in the metal paste X and to more reliably form the first and second active metal layers 270 and 280. In addition, the content of silver (Ag) in the first alloy is not particularly limited, but is preferably approximately equal to or higher than 60% by weight and approximately equal to or lower than 80% by weight.

In addition, an average particle size (median size of d50) of the first particle A is not particularly limited. It is preferable that the first particle has a smaller average particle size in consideration of the sizes of the through holes 213 and 215. Specifically, the average particle size is preferably equal to or less than 40 μm, is preferably equal to or less than 10 μm, and is more preferably equal to or less than 5 μm. Thus, it is possible to suppress the deactivation of the first particle A due to surface oxidation. In addition, it is also possible to secure the workability of filling a via having a small diameter. Accordingly, productivity is improved, and it is possible to manufacture the base substrate 210 with excellent performance.

On the other hand, the second particle B is constituted by the second alloy (M₆-Ni-based alloy) containing a metal of Group VI M₆ and nickel. A metal having a high melting point such as a metal of Group VI M₆ is used, thereby allowing the second alloy to have a melting point sufficiently higher than that of the first alloy. Therefore, it is possible to form the first and second metal wirings 250 and 260 without melting the second particle B in the third process. Accordingly, as will be described later, the shape retaining properties and adhesion of the first and second metal wirings 250 and 260, filling properties into the through holes 213 and 215, and the like are improved. Meanwhile, any one of chromium (Cr), molybdenum (Mo), and tungsten (W) may be used as the metal of Group VI M₆, but tungsten (W) is preferably used among these metals. Among these metals, tungsten (W) has the highest melting point, and thus it is possible to further increase the melting point of the second alloy, thereby allowing the above-mentioned effect to be more effectively exhibited.

The content of the metal of Group VI M₆ in the second alloy is not particularly limited, but is preferably, for example, approximately equal to or higher than 80% by weight and approximately equal to or lower than 99.9% by weight. Thus, it is possible to maintain a sufficiently high melting point of the second alloy as compared with the melting point of the first alloy. Meanwhile, the second particle B according to this embodiment is constituted by an alloy containing a metal of Group VI M₆ and nickel (Ni). However, the second particle contains a small amount of nickel (Ni), and thus it is possible to improve the adhesion between the second particle B and silver (Ag) and copper (Cu) contained in the first particle A. Therefore, it is possible to form the first and second metal wirings 250 and 260 with higher adhesion. The content of nickel (Ni) in the second alloy is not particularly limited, but is preferably approximately equal to or higher than 0.1% by weight and approximately equal to or lower than 20% by weight.

In addition, an average particle size (median size of d50) of the second particle B is not particularly limited. It is preferable that the second particle has a smaller average particle size in consideration of the sizes of the through holes 213 and 215. Specifically, the average particle size is preferably equal to or less than 40 μm, is preferably equal to or less than 10 μm, and is more preferably equal to or less than 5 μm. Thus, it is also possible to secure the workability of filling the through holes 213 and 215 having a small diameter. In addition, it is possible to increase the filling density of the second particle B in the through holes 213 and 215. Accordingly, productivity is improved, and it is possible to manufacture the base substrate 210 with excellent performance.

Meanwhile, a metal particle constituted by a metal of Group VI M₆ may be used as the second particle B.

The first particle A and the second particle B have been described so far. A weight ratio of the first particle A to the second particle B is not particularly limited and varies depending on the content of the metal of Group IV M₄ in the first alloy. However, for example, the weight ratio is preferably approximately equal to or greater than 35:65 and approximately equal to or less than 85:15 and is more preferably approximately equal to or greater than 50:50 and approximately equal to or less than 70:30. In addition, the content of the metal of Group IV M₄ is preferably approximately equal to or higher than 0.7% by weight and approximately equal to or lower than 17.0% by weight and is more preferably approximately equal to or higher than 3.0% by weight and approximately equal to or lower than 8.0% by weight with respect to the total weight of the first particle A and the second particle B. Thereby, a sufficient amount of metal of Group IV M₄ can be secured in the metal paste X, and thus it is possible to more reliably form the first and second active metal layers 270 and 280. Meanwhile, when the content of the metal of Group IV M₄ with respect to the total weight of the first particle A and the second particle B is less than the above-mentioned lower limit, the amount of metal of Group IV M₄ is insufficient, and thus there is a concern that the first and second active metal layers 270 and 280 may not be formed to have a sufficient thickness. On the other hand, when the content of the metal of Group IV M₄ with respect to the total weight of the first particle A and the second particle B exceeds the above-mentioned upper limit, the amount of metal of Group IV M₄ becomes excessive, and thus there is a concern that the first and second active metal layers 270 and 280 may become brittle.

A well-known binder can be used as the binder C. For example, it is possible to use one material or a mixture of two or more materials selected from an acrylic resin such as polyacrylic acid ester or polymethacrylic acid ester, a cellulose-based resin such as methyl cellulose, hydroxymethyl cellulose, nitrocellulose, or cellulose acetate butyrate, a vinyl group-containing resin such as polyvinyl butyral, polyvinyl alcohol, or polyvinyl chloride, a hydrocarbon resin such as polyolefin, an oxygen-containing resin such as polyethylene oxide, and the like.

The metal paste X has been described so far. In addition to the first particle A, the second particle B, and the binder C, the metal paste X may contain, for example, an organic solvent, a dispersing agent, or a plasticizer when necessary.

### Process of Applying Metal Paste X to Ceramic Sintered Substrate 211

As shown in FIG. 5A, the through holes 213 and 215 of the ceramic sintered substrate 211 are filled with the metal paste X, and the metal paste X is disposed on the top surface and the bottom surface of the ceramic sintered substrate 211 into a shape corresponding to the shapes of the internal terminals 253 and 263 and the mounting terminals 255 and 265 to thereby form metal paste layers X1 and X2. Although a method of disposing the metal paste X at the ceramic sintered substrate 211 is not particularly limited, for example, a screen printing method can be used.

### Third Process

Next, as shown in FIG. 5B, the metal paste layers X1 and X2 disposed at the ceramic sintered substrate 211 are baked to form the first and second metal wirings 250 and 260 and the first and second active metal layers 270 and 280. It is preferable that the baking of the metal paste layers X1 and X2 is performed under temperature conditions as shown in FIG. 6.

As shown in FIG. 6, the baking includes a first temperature raising process 401 of raising a temperature, a binder removing process 402 of removing the binder C and the like while maintaining a target temperature in the first temperature raising process 401 substantially constant, a second temperature raising process 403 of raising the temperature again, a baking process 404 of baking the metal paste layers X1 and X2 while maintaining a target temperature in the second temperature raising process substantially constant, and a cooling process 405.

### First Temperature Raising Process 401

First, the ceramic sintered substrate 211 at which the metal paste layers X1 and X2 are disposed is disposed within a chamber, and the inside of the chamber is set to be in a vacuum atmosphere (for example, equal to or lower than 1.33×10 ⁻³ Pa). Thus, it is possible to prevent titanium (Ti) in the metal paste layers X1 and X2 from being oxidized and to form the first and second active metal layers 270 and 280 with good quality. The vacuum atmosphere is maintained also in the following binder removing process 402, second temperature raising process 403, baking process 404, and cooling process 405. Meanwhile, the inside of the chamber may be set to be in a non-oxidizing atmosphere such as an atmosphere filled with an argon (Ar) gas, instead of the vacuum atmosphere. Similarly to the vacuum atmosphere, it is possible to form the first and second active metal layers 270 and 280 with good quality under the atmosphere filled with an argon gas.

Next, the temperature inside the chamber is raised to heat the metal paste layers X1 and X2. A target temperature (peak temperature) T1 in this process is a temperature which is lower than the melting point of the first particle A and which is capable of evaporating and removing the binder C, the organic solvent, moisture, and the like in the metal paste layers X1 and X2. The target temperature T1 is not particularly limited and varies depending on the type of binder C and the melting point of the first particle A. However, the target temperature is preferably, for example, approximately equal to or higher than 350° C. and approximately equal to or lower than 450° C.

In addition, a temperature rise amount per hour (temperature rise rate: ° C./h) in this process is not particularly limited. However, for example, the temperature rise amount is preferably approximately equal to or higher than 150° C./h and approximately equal to or lower than 250° C./h, and is more preferably approximately 200° C./h. Thus, it is possible to raise the temperature inside the chamber over a sufficient period of time. In addition, it is possible to sufficiently raise the temperatures of the metal paste layers X1 and X2 even in a vacuum where heat is not likely to be transferred. Therefore, it is possible to reduce separation between a setting temperature inside the chamber and the actual temperatures of the metal paste layers X1 and X2 and to perform the subsequent binder removing process 402 under more accurate temperature conditions. As a result, it is possible to more reliably remove the binder C and the like from the metal paste layers X1 and X2 in the binder removing process 402. Meanwhile, when the temperature rise rate is less than the above-mentioned lower limit, there is a concern that the temperatures of the metal paste layers X1 and X2 may not be sufficiently increased depending on the size of the chamber and an atmosphere environment. In contrast, when the temperature rise rate exceeds the above-mentioned lower limit, depending on the size of the chamber and an atmosphere environment an improvement in the above-mentioned effect of reducing separation between a setting temperature inside the chamber and the actual temperatures of the metal paste layers X1 and X2 may be scarcely expected, and thus there is a concern of the processing time of this process just being lengthened.

### Binder Removing Process 402

In this process, the target temperature T1 in the first temperature raising process 401 is maintained substantially constant. According to this process, it is possible to remove materials (that is, the binder C, the organic solvent, moisture, and the like), other than the first and second particles A and B, from the metal paste layers X1 and X2 while preventing the first particle A from being melted. Thus, it is possible to more reliably bake the metal paste layers X1 and X2 (melt the first particle A). A holding time in this process is not particularly limited and varies depending on the amount of binder C, and the like. However, for example, the holding time is preferably approximately equal to or longer than 30 minutes and approximately equal to or shorter than 2 hours and is more preferably approximately equal to or longer than 30 minutes and approximately equal to or shorter than one hour. Thus, it is possible to effectively remove the binder C and the like from the metal paste layers X1 and X2. Meanwhile, when the holding time is less than the above-mentioned lower limit, it is not possible to sufficiently remove the binder C and the like from the metal paste layers X1 and X2 depending on the content of the binder C. For this reason, the binder C and the like remain until the subsequent baking process 404, and thus there is a concern that the remaining binder C and the like may hinder the first particle A from being melted. In contrast, when the holding time exceeds the above-mentioned upper limit, this process is just excessively lengthened depending on the content of the binder C. Thus, a further improvement in an effect of removing the binder C and the like may not be expected. Further, the whole baking time may be lengthened, and thus there is a concern of thermal damage to the ceramic sintered substrate 211 being increased.

Meanwhile, in the binder removing process 402 according to this embodiment, the target temperature T1 in the first temperature raising process 401 is maintained substantially constant, but is not limited thereto. The target temperature may be raised if the target temperature is lower than the temperature rise rate (temperature rise amount per unit time) in the first and second temperature raising processes 401 and 403. In contrast, the target temperature may be lowered. However, when the target temperature is lowered, a temperature that has to be raised in the subsequent second temperature raising process 403 becomes larger. For this reason, it is preferable that the target temperature is raised or is maintained substantially constant as in this embodiment. In addition, when the target temperature is raised, the temperature rise rate thereof is not particularly limited, but is preferably approximately equal to or higher than 5° C./h or approximately equal to or lower than 50° C./h. Thereby, it is possible to suppress the excessive heating of the metal paste layers X1 and X2 during the binder removing process. Thus, for example, it is possible to effectively prevent, for example, the first particle A from being unintentionally melted.

### Second Temperature Raising Process 403

In this process, after the binder removing process 402 is finished, the temperature inside the chamber is raised again to heat the metal paste layers X1 and X2. A target temperature (peak temperature) T2 in the second temperature raising process 403 is a temperature which is higher than the melting point of the first particle A and which is lower than the melting point of the second particle B. Thus, it is possible to melt the first particle A while preventing the second particle B from being melted. In addition, it is preferable that the target temperature T2 is lower than a baking temperature of the ceramic sintered substrate 211. Thus, it is possible to reduce thermal damage to the ceramic sintered substrate 211, thereby obtaining the base substrate 210 with high reliability. The target temperature T2 is not particularly limited and varies depending on the melting points of the first and second particles A and B. However, for example, the target temperature is preferably approximately equal to or higher than 800° C. and approximately equal to or lower than 1000° C.

In addition, the temperature rise amount per hour (temperature rise rate: ° C./h) in this process is not particularly limited. However, for example, the temperature rise amount is preferably equal to or higher than 150° C./h and equal to or lower than 250° C./h and is more preferably approximately 200° C./h. In this manner, the temperature inside the chamber is raised over a sufficient period of time, and thus it is possible to sufficiently raise the temperatures of the metal paste layers X1 and X2 even in a vacuum where heat is not likely to be transferred. For this reason, it is possible to reduce separation between a setting temperature inside the chamber and the actual temperatures of the metal paste layers X1 and X2 and to perform the subsequent baking process 404 under more accurate temperature conditions. As a result, it is possible to more reliably form the first and second active metal layers 270 and 280, and the formed first and second active metal layers 270 and 280 have better quality. Meanwhile, when the temperature rise rate is less than the above-mentioned lower limit, there is a concern that the temperatures of the metal paste layers X1 and X2 may not be sufficiently increased depending on the size of the chamber and an atmosphere environment. In contrast, when the temperature rise rate exceeds the above-mentioned lower limit, depending on the size of the chamber and an atmosphere environment an improvement in the above-mentioned effect of reducing separation between a setting temperature inside the chamber and the actual temperatures of the metal paste layers X1 and X2 may be scarcely expected, and thus there is a concern of the processing time of this process just being lengthened.

### Baking Process 404

In this process, the target temperature T2 in the second temperature raising process 403 is maintained substantially constant. As shown in FIG. 5C, according to this process, it is possible to form the first and second active metal layers 270 and 280 and the first and second metal wirings 250 and 260 by melting the first particle A.

Specifically, the first particle A is melted by this process, and titanium (Ti) existing in the first particle A reacts with the ceramic component of the ceramic sintered substrate 211, and thus the first and second active metal layers 270 and 280 are formed in the interfaces between the metal paste layers X1 and X2 and the ceramic sintered substrate 211. Further, silver (Ag) and copper (Cu) which exist in the first particle A flow to permeate the second particle B. Thus, the first and second metal wirings 250 and 260 are formed on the first and second active metal layers 270 and 280.

In this manner, the first and second active metal layers 270 and 280 are formed between the ceramic sintered substrate 211 and the first and second metal wirings 250 and 260, and thus the adhesion between the ceramic sintered substrate 211 and the first and second metal wirings 250 and 260 is improved, thereby obtaining the base substrate 210 with excellent airtightness and mechanical strength. In this process, only the first particle A is melted without substantially melting the second particle B, and thus it is possible to effectively suppress the wetting spreading and the sagging and running of the metal paste layers X1 and X2 by the second particle B. For this reason, the wiring shape retaining properties thereof are improved, and thus it is possible to form the first and second metal wirings 250 and 260 which are closer to the design shape and which have excellent electrical characteristics. Therefore, the first and second metal wirings 250 and 260 with high reliability are obtained. In addition, for example, the temperature of this process can be decreased as compared with a case where the second particle B is melted, and thus it is possible to reduce thermal damage to the ceramic sintered substrate 211.

The holding time of this process is not particularly limited and varies depending on the volume of the metal paste layers X1 and X2, and the like. However, for example, the holding time is preferably approximately equal to or longer than 10 minutes and approximately equal to or shorter than one hour and is more preferably approximately 30 minutes. Thus, it is possible to sufficiently melt the first particle A and to more reliably form the first and second active metal layers 270 and 280. Meanwhile, when the holding time is less than the above-mentioned lower limit, it is not possible to sufficiently melt the first particle A depending on the volume of the metal paste layers X1 and X2 (the content of the first particle A) and the like. Thus, there is a concern that the first and second active metal layers 270 and 280 may not be sufficiently formed. In contrast, when the holding time exceeds the above-mentioned upper limit, this process is just excessively lengthened depending on the volume of the metal paste layers X1 and X2 (the content of the first particle A) and the like. Thus, there is a concern of thermal damage to the ceramic sintered substrate 211 being increased.

Meanwhile, in the baking process 404 according to this embodiment, the target temperature T2 is maintained substantially constant. However, the target temperature is not limited thereto as long as the target temperature higher than the melting point of the first particle A and lower than the melting point of the second particle B is maintained. The target temperature may be raised or lowered. In addition, an increase and decrease in the target temperature may be alternatively repeated.

### Cooling Process 405

In this process, the temperature is gradually lowered from the target temperature T2 to thereby cool the ceramic sintered substrate 211, the first and second active metal layers 270 and 280, and the first and second metal wirings 250 and 260 to, for example, room temperature. Thus, the base substrate 210 is obtained. A temperature fall amount per hour (temperature fall rate: ° C./h) in this process is not particularly limited. However, the temperature fall amount is preferably approximately equal to or higher than 10° C./h and approximately equal to or lower than 100° C./h, and is more preferably approximately equal to or higher than 40° C./h and approximately equal to or lower than 60° C./h. In this manner, the cooling is performed over a sufficient period of time, and thus it is possible to effectively reduce the occurrence of a crack and the like in the ceramic sintered substrate 211 from differences in a thermal expansion coefficient between the ceramic sintered substrate 211, the first and second active metal layers 270 and 280, and the first and second metal wirings 250 and 260. Therefore, the base substrate 210 with excellent airtightness and mechanical strength is obtained.

According to the above-mentioned method of manufacturing the base substrate 210, the base substrate 210 having excellent adhesion between the ceramic sintered substrate 211 and the first and second metal wirings 250 and 260 and having excellent shape retaining properties and electrical characteristics of the first and second metal wirings 250 and 260 is obtained. In addition, the occurrence of a crack in the ceramic sintered substrate 211 can be reduced, and thus it is possible to prevent the mechanical strength of the base substrate from being decreased and to improve the yield of the base substrate 210.

### 3. Electronic Apparatus

Next, an electronic apparatus including the electronic device 100 will be described.

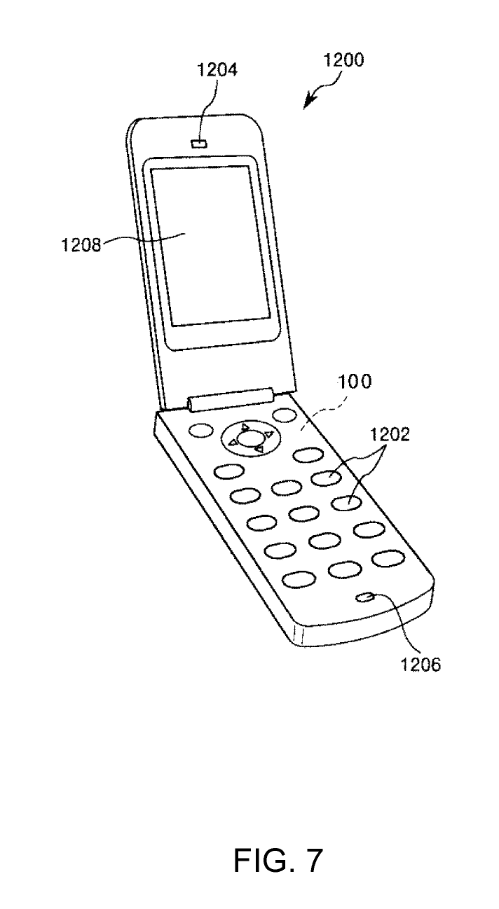

FIG. 7 is a perspective view showing the configuration of a mobile (or notebook) personal computer to which an electronic apparatus according to the invention is applied. In the drawing, a personal computer 1100 includes a main body 1104 having a keyboard 1102 and a display unit 1106 having a display portion 1108, and the display unit 1106 is supported so as to be rotatable with respect to the main body 1104 through a hinge structure. The electronic device 100 functioning as a filter, a resonator, a reference clock, and the like is built in the personal computer 1100.

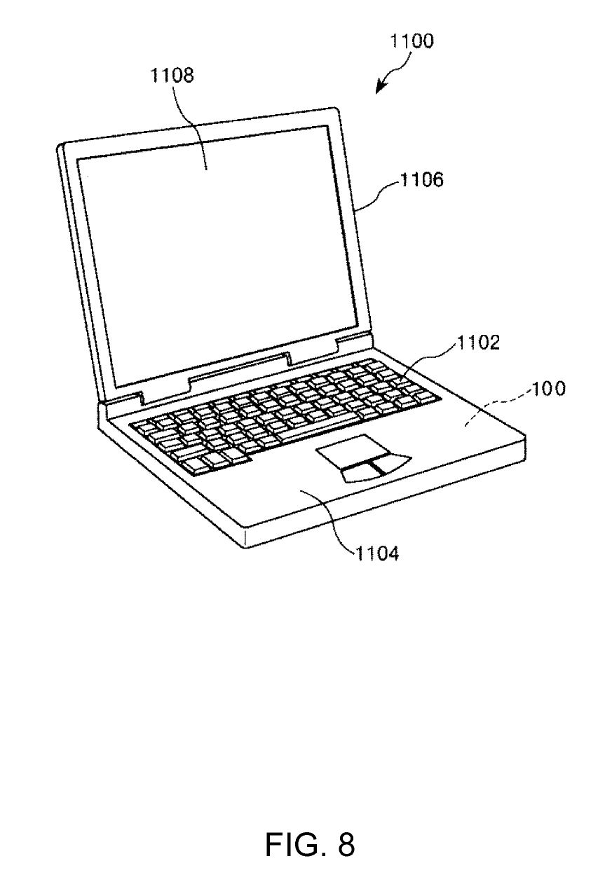

FIG. 8 is a perspective view showing the configuration of a mobile phone (a PHS is also included) to which an electronic apparatus according to the invention is applied. In the drawing, a mobile phone 1200 includes a plurality of operation buttons 1202, an earpiece 1204, and a mouthpiece 1206, and the display portion 1208 is disposed between the operation buttons 1202 and the earpiece 1204. The electronic device 100 functioning as a filter, a resonator, a reference clock, and the like is built in the mobile phone 1200.

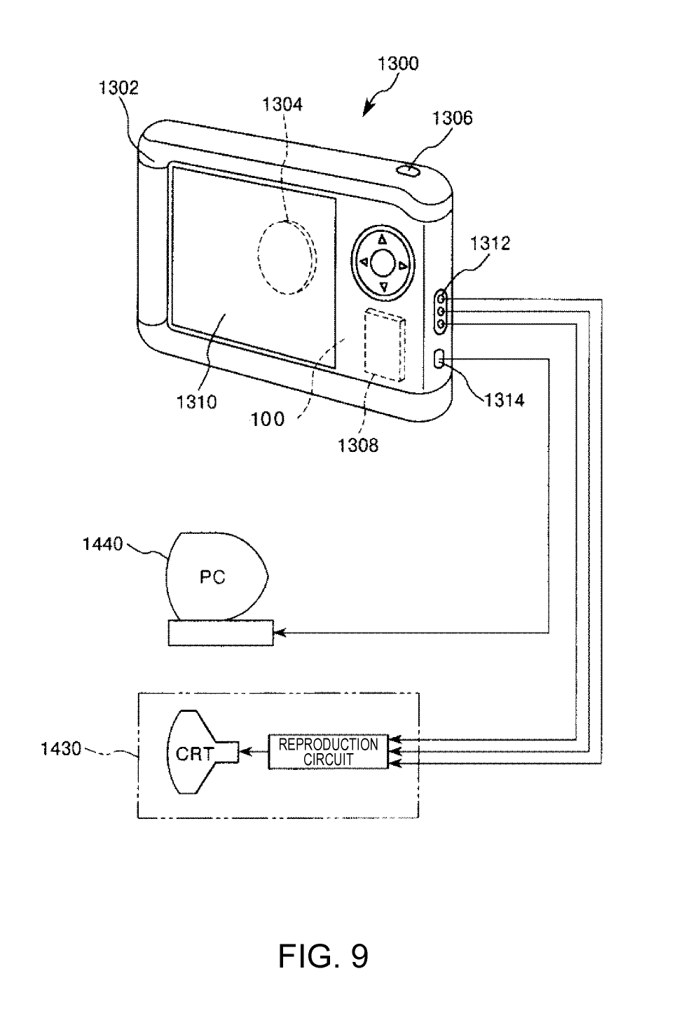

FIG. 9 is a perspective view showing the configuration of a digital still camera to which an electronic apparatus according to the invention is applied. Meanwhile, connection with an external device is simply shown in FIG. 9. Here, a silver halide photograph film is exposed to light according to an optical image of a subject in a typical camera, while a digital still camera 1300 generates an imaging signal (image signal) by performing photoelectric conversion of an optical image of a subject using an imaging element, such as a charge coupled device (CCD).

A display portion 1310 is provided on the back of a case (body) 1302 in the digital still camera 1300, so that display based on the imaging signal of the CCD is performed. The display portion functions as a viewfinder that displays a subject as an electronic image. In addition, a light receiving unit 1304 including an optical lens (imaging optical system), a CCD, and the like is provided on the front side (back side in FIG. 9) of the case 1302.

When a photographer checks a subject image displayed on the display unit and presses a shutter button 1306, an imaging signal of the CCD at that point in time is transferred and stored in a memory 1308. In addition, in the digital still camera 1300, a video signal output terminal 1312 and an input/output terminal for data communication 1314 are provided on the side surface of the case 1302. In addition, as shown in FIG. 9, a television monitor 1430 is connected to the video signal output terminal 1312 and a personal computer 1440 is connected to the input/output terminal for data communication 1314 when necessary. In addition, an imaging signal stored in the memory 1308 may be output to the television monitor 1430 or the personal computer 1440 by a predetermined operation. The electronic device 100 functioning as a filter, a resonator, a reference clock, and the like is built in the digital still camera 1300.

Meanwhile, the electronic apparatus including the electronic device can be applied not only to the personal computer (mobile personal computer) shown in FIG. 7, the mobile phone shown in FIG. 8, and the digital still camera shown in FIG. 9 but also to an ink jet type discharge apparatus (for example, an ink jet printer), a laptop type personal computer, a television, a video camera, a video tape recorder, a car navigation apparatus, a pager, an electronic organizer (an electronic organizer with a communication function is also included), an electronic dictionary, an electronic calculator, an electronic game machine, a word processor, a workstation, a video phone, a television monitor for security, electronic binoculars, a POS terminal, medical equipment (for example, an electronic thermometer, a sphygmomanometer, a blood sugar meter, an electrocardiographic measurement device, an ultrasonic diagnostic apparatus, and an electronic endoscope), a fish detector, various measurement apparatuses, instruments (for example, instruments for vehicles, aircraft, and ships), and a flight simulator.

### 4. Moving Object

Next, a moving object including the electronic device 100 will be described.

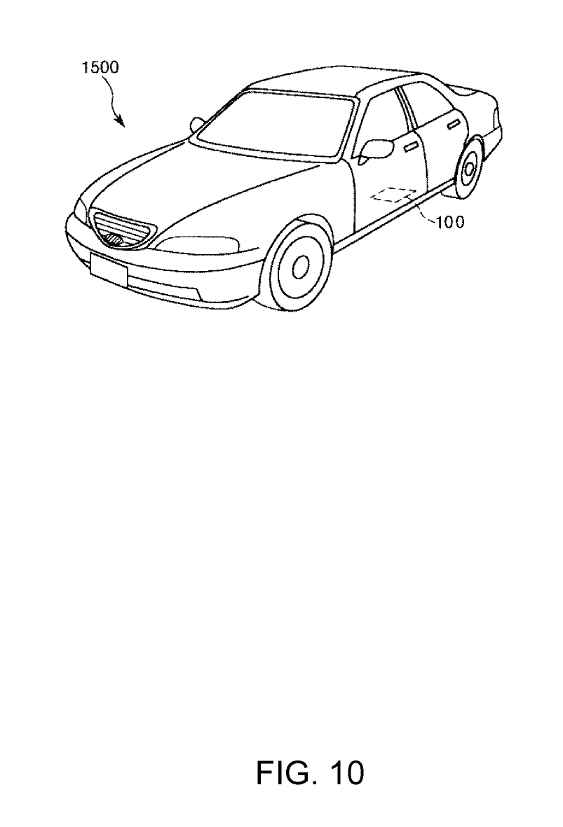

FIG. 10 is a perspective view showing a vehicle to which a moving object according to the invention is applied. The electronic device 100 is mounted in a vehicle 1500. The electronic device 100 can be widely applied to an electronic control unit (ECU) such as, for example, a keyless entry, an immobilizer, a car navigation system, a car air-conditioner, an anti-lock brake system (ABS), an airbag, a tire pressure monitoring system (TPMS), an engine control, a battery monitor of a hybrid vehicle or an electric vehicle, and a vehicle body position control system.

The wiring board, the method of manufacturing a wiring board, the electronic device, the electronic apparatus, and the moving object according to the invention have been described so far on the basis of the embodiments shown in the drawings, but the invention is not limited thereto. The configuration of each portion may be replaced with an arbitrary configuration having the same function. In addition, other arbitrary components may be added to the invention. Further, the embodiments may be appropriately combined.

In the above-described embodiment, a description has been given of a configuration in which a through hole is formed as a concave portion provided in a ceramic sintered substrate, but a bottomed concave portion may be used instead of the through hole. That is, a bottomed concave portion having an opening in the top surface or bottom surface thereof may be used.

### EXAMPLES

### 1. Manufacture of Base Substrate (Wiring Board)

### Example 1

### Manufacture of Ceramic Sintered Substrate

First, a single-layered ceramic green sheet was prepared. The ceramic green sheet was used which contains aluminum oxide (alumina) as its main component and which is obtained by mixing aluminum oxide and a binder at a ratio of 89:19 (w %) and molding the mixture into a sheet shape. In addition, the ceramic green sheet had a size in which (length×width×thickness) is (60 mm×53 mm×0.2 mm). A through hole having a diameter of 250 μm was formed in the ceramic green sheet. The ceramic green sheet was baked to thereby obtain a ceramic sintered substrate. The baking was performed by first disposing the ceramic green sheet inside a chamber (manufactured by Nems Co., Ltd.: ED40×40×40), raising the temperature inside the chamber at a temperature rise rate of 200° C./h in a hydrogen gas atmosphere, and performing baking thereon for 30 minutes at 1500° C.

### Manufacture of Metal Paste

Alloy powder (average particle size d50=30 μm: manufactured by Nais Co., Ltd., V1008T) constituted by a Ti—Ag—Cu alloy (first alloy) was prepared as a first particle. The content of Ti in the first alloy was 2% by weight, the content of Ag was 68% by weight, and the content of Cu was 30% by weight. In addition, alloy powder (average particle size d50=3 μm: manufactured by Epson Atmix Corporation) constituted by a W—Ni alloy (second alloy) was prepared as a second particle. The content of W in the second alloy was 98% by weight, and the content of Ni was 2% by weight. Then, the first particle and the second particle were mixed at a weight ratio of 50:50 to thereby obtain a metal mixture. Further, the metal mixture was mixed with an organic vehicle to thereby obtain a metal paste. Meanwhile, a mixture of hydrorefining light distillation was used as the organic vehicle, and the content of the metal mixture in the metal paste was set to 20% by weight.

### Application of Metal Paste

Next, the through hole of the ceramic sintered substrate was filled with a metal paste by using a screen printing method using a metal mask. Then, a metal paste having a predetermined shape was printed on the top surface and the bottom surface of the ceramic sintered substrate by using a screen printing method using a metal mask. Thus, the printed ceramic sintered substrate was obtained.

### Baking

Next, the printed ceramic sintered substrate was disposed inside the chamber, and the inside of the chamber was set to be in a vacuum atmosphere of equal to or less than 1.33×10⁻³ Pa. Then, the temperature inside the chamber (the temperature of the printed ceramic sintered substrate) was raised to 400° C. at a temperature rise rate of 200° C./h, and the temperature of 400° C. was held for one hour. Next, the temperature inside the chamber (the temperature of the printed ceramic sintered substrate) was raised to 900° C. at a temperature rise rate of 200° C./h, and the temperature of 900° C. was held for one hour. Subsequently, the temperature inside the chamber (the temperature of the printed ceramic sintered substrate) was lowered to room temperature at a temperature fall rate of 50° C./h. Thus, the metal paste was baked, an active metal layer was formed at an interface with the ceramic sintered substrate, and a metal wiring was formed on the active metal layer.

As described above, a base substrate was obtained.

### Examples 2 to 16

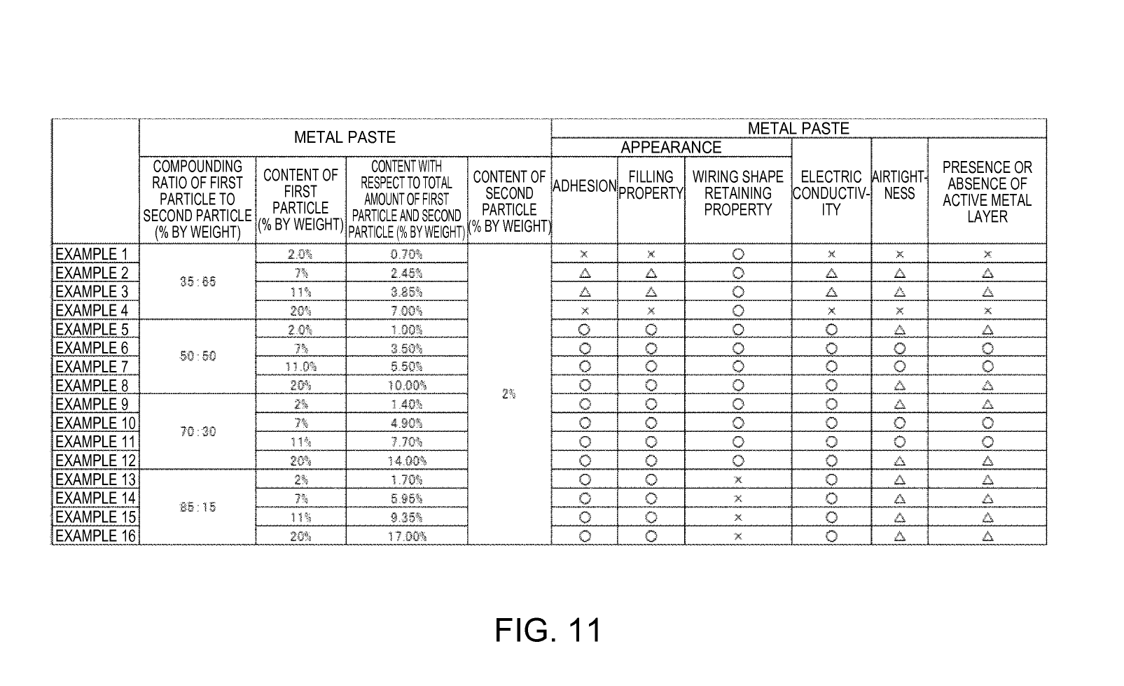

Base substrate was obtained in the same manner as in Example 1 mentioned above except that the content of Ti in the first alloy and the weight ratio of the first particle to the second particle in the metal mixture were set as shown in Table 1 of FIG. 11.

### 2. Evaluation

The base substrates of Examples 1 to 16 were evaluated as follows. The evaluation results are shown in Table 1 of FIG. 11.

### Adhesiveness Between Metal Wiring and Active Metal Layer

It was evaluated whether the formed metal wiring and active metal layer were peeled off from the ceramic sintered substrate or whether damage such as a crack has occurred in the metal wiring and the active metal layer. This evaluation was performed by manufacturing ten base substrates of Examples 1 to 16 and calculating the number of base substrates in which peeling or a crack has occurred. An example having no base substrate in which peeling or a crack has occurred was indicated by “A”, an example having one or two base substrates in which peeling or a crack has occurred was indicated by “B”, and an example having three or more base substrates in which peeling or a crack has occurred was indicated by “C”.

Filling Property into Through Hole

It was evaluated whether the through hole was densely filled with the formed metal wiring. This evaluation was performed by observing the cross-section of the through hole (via) using an SEM and determining whether a gap was formed between the inner circumferential surface of the through hole and the active metal layer. In addition, this evaluation was performed by manufacturing one hundred base substrates of Examples 1 to 16 and calculating the number of base substrates in which a gap had been generated. An example having no base substrate in which a gap had been generated was indicated by “A”, an example having one or two base substrates in which a gap had been generated was indicated by “B”, and an example having three or more base substrates in which a gap had been generated was indicated by “C”.

### Wiring Shape Retaining Property

It was evaluated whether the formed metal wiring maintains the shape before the baking. This evaluation was performed by observing the metal wiring using an electron microscope and on the basis of changes in a wiring width (area) before and after the baking. An example having a rate of change in the wiring width before and after the baking being equal to or lower than 5% was indicated by “A”, and an example having a rate of change exceeding 5% was indicated by “C”. Meanwhile, Examples 1 to 16 were evaluated using an average value of ten base substrates.

### Electric Conductivity

It was evaluated whether the formed metal wiring had excellent conductivity. This evaluation was performed by aligning the metal wiring of the base substrate of each of Examples 1 to 16 to a length of 3 mm and a thickness of 0.005 mm and measuring the conduction resistance of the metal wiring. A case where the conduction resistance was less than 2Ω was indicated by “A”, and a case where the conduction resistance was equal to or greater than 2Ω was indicated by “C”. Examples 1 to 16 were evaluated using an average value of ten base substrates.

### Airtightness

The airtightness of the manufactured base substrate was evaluated. This evaluation was performed by dropping alcohol onto one surface of the ceramic sintered substrate and determining whether the dropped alcohol has oozed out on the other surface through a via (through hole). In addition, this evaluation was performed by manufacturing ten base substrates of Examples 1 to 16 and calculating the number of wiring boards in which oozing-out has occurred. An example having no base substrate in which oozing-out has occurred was indicated by “A”, an example having one or two base substrates in which oozing-out has occurred was indicated by “B”, and an example having three or more base substrates in which oozing-out has occurred was indicated by “C”.

### Presence or Absence of Active Metal Layer

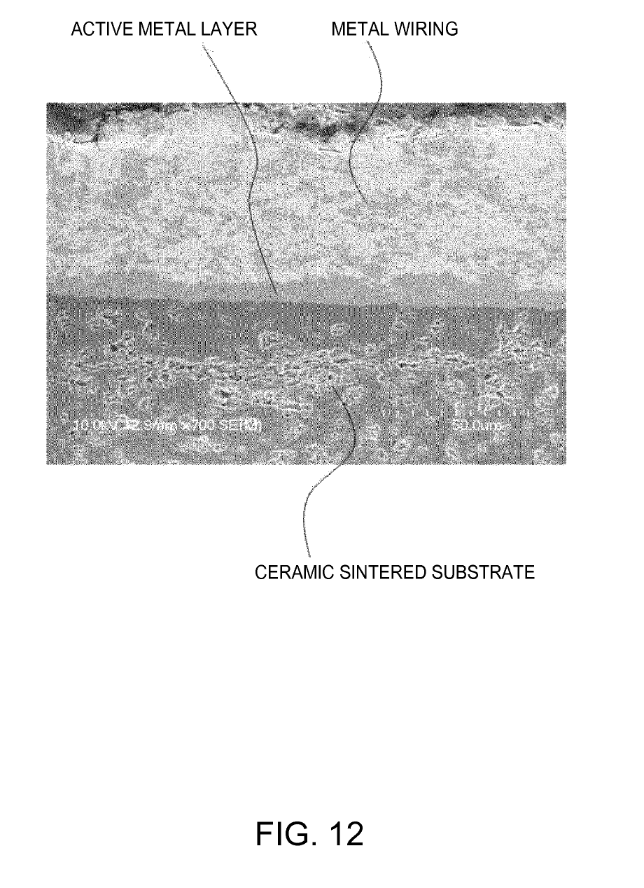

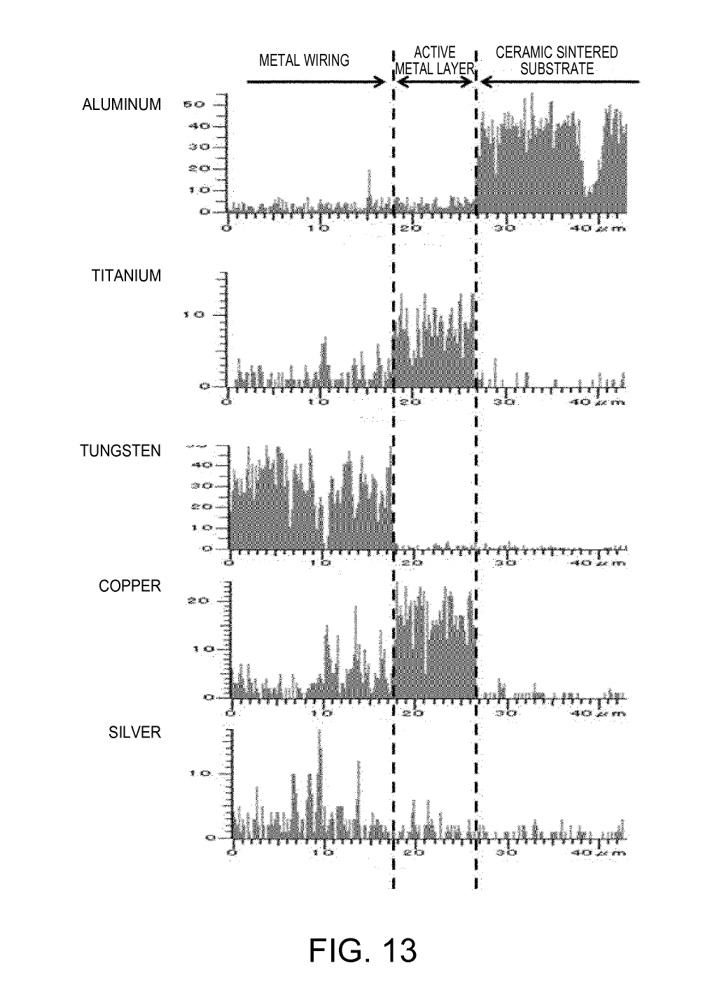

It was evaluated whether an active metal layer has been formed in the base substrate, through SEM observation. In addition, this evaluation was performed by manufacturing ten base substrates of Examples 1 to 16 and calculating the number of base substrates in which an active metal layer has not been formed. An example having no base substrate in which an active metal layer has not been formed was indicated by “A”, an example having one or two base substrates in which an active metal layer has not been formed was indicated by “B”, and an example having three or more base substrates in which an active metal layer has not been formed was indicated by “C”. Meanwhile, an SEM image obtained by capturing an image of the cross-section of the base substrate of Example 7 is representatively shown in FIG. 12, and the content of metals (aluminum, titanium, tungsten, copper, and silver) which are contained in layers is shown in FIG. 13.

### 3. Evaluation Results

As shown in Table 1 of FIG. 11, it can be understood that the base substrates of Examples 5 to 12 having a weight ratio of the first particle to the second particle being 50:50 to 70:30 have excellent evaluation results as a whole, as compared with Examples 1 to 4 and Examples 13 to 16 having a weight ratio of the first particle to the second particle being 35:65 and 85:15. In addition, it can be understood that Examples 6, 7, 10, and 11 having the content of Ti with respect to the total amount of the first particle and the second particle being 3.5% by weight to 7.7% by weight, among Examples 5 to 12, have further excellent evaluation results.

The entire disclosure of Japanese Patent Application No. 2014-019787, filed Feb. 4, 2014 is expressly incorporated by reference herein.

What is claimed is:

1. A wiring board comprising:
a substrate which includes a concave portion having an opening in a surface thereof;
a metal wiring which is disposed so as to be connected to the surface of the substrate and the inside of the concave portion; and
an active metal layer which is disposed between the metal wiring and the substrate and contains an active metal active for a component contained in the substrate.

2. The wiring board according to claim 1,
wherein the substrate is a ceramic substrate, and
wherein the active metal layer is formed by reaction occurring between the active metal and a ceramic component contained in the ceramic substrate.

3. The wiring board according to claim 2, wherein the active metal layer contains a metal belonging to Group IV of a periodic table as the active metal.

4. The wiring board according to claim 3, wherein the active metal layer contains titanium as the active metal.

5. The wiring board according to claim 1, wherein the metal wiring contains a metal belonging to Group VI of a periodic table, silver, and copper.

6. The wiring board according to claim 5, wherein the metal wiring contains tungsten as the metal belonging to Group VI.

7. The wiring board according to claim 1, wherein the concave portion is a through hole passing through one principal surface and the other principal surface of the substrate.

8. A method of manufacturing a wiring board, the method comprising:
preparing a substrate that includes a concave portion having an opening in a surface thereof, and a mixture of a first particle constituted by an alloy containing an active metal, which belongs to Group IV of a periodic table and is active for a component contained in the substrate, silver, and copper and a second particle constituted by a metal belonging to Group VI of the periodic table or an alloy containing the metal belonging to Group VI;
disposing the mixture so as to be connected to the surface of the substrate and the inside of the concave portion; and
forming a metal wiring by baking the mixture disposed on the substrate.

9. The method according to claim 8,
wherein the substrate is a ceramic substrate, and
wherein the active metal is active for a ceramic component contained in the ceramic substrate.

10. The method according to claim 9, wherein a baking temperature of the mixture is lower than a baking temperature of the ceramic substrate in the forming of the metal wiring.

11. The method according to claim 8, wherein the first particle contains titanium as the active metal.

12. The method according to claim 8, wherein the second particle contains tungsten as the metal belonging to Group VI.

13. The method according to claim 8, wherein the second particle is an alloy containing the metal belonging to Group VI and nickel.

14. The method according to claim 8, wherein a content of the first particle with respect to a total weight of the first particle and the second particle in the mixture is in a range between equal to or higher than 35% by weight and equal to or lower than 85% by weight.

15. An electronic device comprising:
the wiring board according to claim 1; and
an electronic component which is mounted on the wiring board.

16. An electronic apparatus comprising the electronic device according to claim 15.

17. A moving object comprising the electronic device according to claim 15.
